(19) United States
(12) Patent Application Publication
(10) Pub. No.: US 2025/0331173 A1
(43) Pub. Date: Oct. 23, 2025

(54) SEMICONDUCTOR DEVICES AND METHODS FOR FORMING THE SAME

(71) Applicant: YANGTZE MEMORY TECHNOLOGIES CO., LTD., Wuhan (CN)

(72) Inventors: Yaqin Liu, Wuhan (CN); Liang Chen, Wuhan (CN); Yanwei Shi, Wuhan (CN); Quan Zhang, Wuhan (CN)

(21) Appl. No.: 18/662,137

(22) Filed: May 13, 2024

Related U.S. Application Data
(63) Continuation of application No. PCT/CN2024/089025, filed on Apr. 22, 2024.

(51) Int. Cl. H10B 12/00

(52) U.S. Cl. CPC H10B 12/50; H10B 12/01

(57) ABSTRACT

A semiconductor device includes a memory structure and a peripheral structure coupled to the memory structure. The peripheral structure includes a first doping region, a first array of transistor structures, a second array of transistor structures, and a first tap structure. The first array of transistor structures and the second array of transistor structures are arranged in the first doping region configured in a first direction and a second direction perpendicular to the first direction. Each transistor of the first array of transistor structures and the second array of transistor structures comprises a source structure, a gate structure, and a drain structure arranged along the first direction in a plan view of the semiconductor device. The first tap structure is arranged between the first array of transistor structures and the second array of transistor structures extending in the first direction.

### CROSS-REFERENCE TO RELATED APPLICATIONS

The present application claims the benefit of priority to International Application No. PCT/CN2024/089025, filed on Apr. 22, 2024, which is hereby incorporated by reference in its entirety.

### BACKGROUND

The present disclosure relates to semiconductor devices and fabrication methods thereof, and specifically, relates to the three-dimensional (3D) memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture includes a memory array and peripheral circuits for facilitating operations of the memory array.

### SUMMARY

Implementations of semiconductor devices and methods for forming the same are disclosed herein.

In one aspect, a semiconductor device is disclosed. The semiconductor device includes a memory structure and a peripheral structure coupled to the memory structure. The peripheral structure includes a first doping region, a first array of transistor structures, a second array of transistor structures, and a first tap structure. The first array of transistor structures and the second array of transistor structures are arranged in the first doping region configured in a first direction and a second direction perpendicular to the first direction. Each transistor of the first array of transistor structures and the second array of transistor structures comprises a source structure, a gate structure, and a drain structure arranged along the first direction in a plan view of the semiconductor device. The first tap structure is arranged between the first array of transistor structures and the second array of transistor structures extending in the first direction.

In some implementations, a width of the first tap structure in the plan view of the semiconductor device in the second direction is between 80 nm and 120 nm.

In some implementations, a first length of the first doping region in the plan view of the semiconductor device in the first direction is greater than a second length of the first tap structure in the plan view of the semiconductor device in the first direction.

In some implementations, the peripheral structure further includes a second doping region adjacent to the first doping region along the first direction, a third array of transistor structures, a fourth array of transistor structures, and a second tap structure. The third array of transistor structures and the fourth array of transistor structures are arranged in the second doping region configured in the first direction and the second direction perpendicular to the first direction. The second tap structure is arranged between the third array of transistor structures and the fourth array of transistor structures extending in the first direction. A first distance between a boundary of the first doping region and the second doping region and the first array of transistor structures is equal to a second distance between the boundary and the third array of transistor structures.

In some implementations, a third distance between the boundary and the first tap structure is between 10 nm and 500 nm.

In some implementations, a fourth distance between the boundary and the second tap structure is equal to the third distance.

In some implementations, the first doping region is a p-well region, the second doping region is an n-well region, and the first doping region and the second doping region are separated by an isolation structure.

In some implementations, the first tap structure is a p-well tap structure, and the second tap structure is an n-well tap structure.

In some implementations, the peripheral structure further includes a third tap structure arranged in the first doping region. The second array of transistor structures is between the first tap structure and the third tap structure in the second direction in the plan view of the semiconductor device.

In some implementations, a fifth distance between the first tap structure and the third tap structure in the second direction is between 0 and 200 μm.

In another aspect, a semiconductor device is disclosed. The semiconductor device includes a memory structure and a peripheral structure coupled to the memory structure. The peripheral structure includes a first doping region, a first array of transistor structures arranged in the first doping region, and a first tap structure arranged in the first doping region. Each transistor of the first array of transistor structures includes a source structure, a gate structure, and a drain structure arranged along a first direction in a plan view of the semiconductor device, and the first tap structure extends in the first direction.

In some implementations, the peripheral structure further includes a second doping region adjacent to the first doping region along the first direction, and the first doping region and the second doping region are separated by an isolation structure, a second array of transistor structures arranged in the second doping region, and a second tap structure arranged in the second doping region extending in the first direction.

In some implementations, a first distance between a boundary of the first doping region and the second doping region and the first array of transistor structures is equal to a second distance between the boundary and the second array of transistor structures.

In some implementations, a third distance between a boundary of the first doping region and the second doping region and the first tap structure is equal to a fourth distance between the boundary and the second tap structure.

In some implementations, a width of the first tap structure in the plan view of the semiconductor device in a second direction perpendicular to the first direction is between 80 nm and 120 nm.

In some implementations, a first length of the first doping region in the plan view of the semiconductor device in the first direction is greater than a second length of the first tap structure in the plan view of the semiconductor device in the first direction.

In still another aspect, a method of forming a semiconductor device is disclosed. The method includes forming a first doping region in a substrate; forming a first array of transistor structures in the first doping region, wherein each transistor of the first array of transistor structures comprises a source, a gate, and a drain arranged along a first direction in a plan view of the semiconductor device; and forming a first tap structure in the first doping region extending in the first direction in the plan view of the semiconductor device.

In some implementations, the method further includes forming a second doping region adjacent to the first doping region along the first direction in the substrate, wherein the first doping region and the second doping region are separated by an isolation structure; forming a second array of transistor structures in the second doping region; and forming a second tap structure in the second doping region extending in the first direction in the plan view of the semiconductor device.

In some implementations, a first distance between a boundary of the first doping region and the second doping region and the first array of transistor structures is equal to a second distance between the boundary and the second array of transistor structures.

In some implementations, a third distance between a boundary of the first doping region and the second doping region and the first tap structure is equal to a fourth distance between the boundary and the second tap structure.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic circuit diagram of an exemplary memory device, according to some implementations of the present disclosure.

FIG. 2 illustrates a schematic plan view of a portion of an exemplary peripheral circuit, according to some implementations of the present disclosure.

FIG. 3 illustrates a schematic plan view of a portion of an exemplary peripheral circuit, according to some implementations of the present disclosure.

FIG. 4 illustrates a schematic plan view of a portion of an exemplary peripheral circuit, according to some implementations of the present disclosure.

FIG. 5 illustrates a schematic plan view of a portion of an exemplary peripheral circuit, according to some implementations of the present disclosure.

FIG. 6 illustrates a block diagram of peripheral circuits provided with various voltages, according to some aspects of the present disclosure.

FIG. 7 illustrates a flowchart of a method for forming a semiconductor device, according to some aspects of the present disclosure.

FIG. 8 illustrates a block diagram of an exemplary system having a memory device, according to some aspects of the present disclosure.

FIG. 9A illustrates a diagram of an exemplary memory card having a memory device, according to some aspects of the present disclosure.

FIG. 9B illustrates a diagram of an exemplary solid-state drive (SSD) having a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures, or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

With the development of 3D memory devices, such as 3D NAND Flash memory devices, the chip size limitation may cause spacings between the peripheral circuits, i.e., page buffer circuits, or high voltage MOS devices, in the transistor circuits to become smaller and smaller in both X- and Y-directions. In some implementations, one or more well taps, i.e., n taps or p taps, may be formed near the boundary of the well regions to provide a bias voltage to the bulk of the transistors. In some cases, the area of the well taps may occupy about 2% of the whole chip area. Thus, it is desirable to reduce the planar areas occupied by the well taps in the peripheral circuits of the 3D memory devices with the increased numbers of peripheral circuits and the transistors thereof.

To address these issues, the present disclosure introduces various solutions in which the arrangement of the well taps, the transistors, and the well regions in the peripheral circuits of the 3D memory device may effectively reduce the whole planar areas of the peripheral circuits.

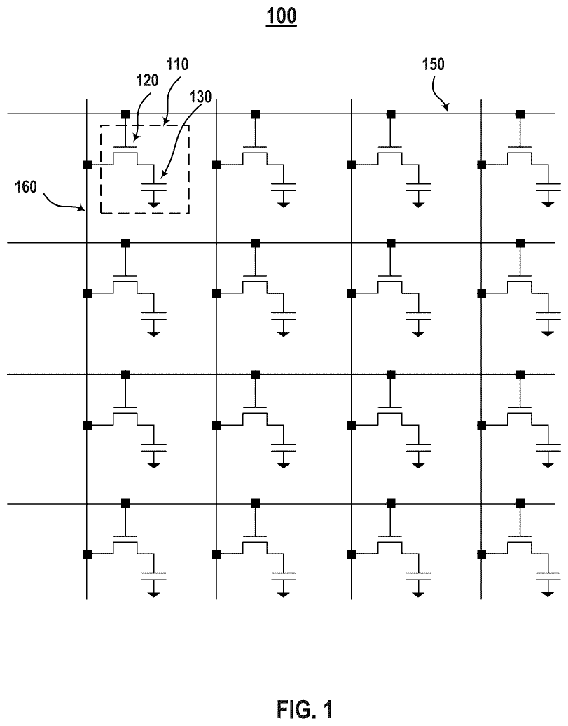

FIG. 1 illustrates a schematic circuit diagram of a memory device 100, according to some implementations of the present disclosure. Memory device 100 may include a memory cell array in which each memory cell 110 includes a vertical transistor 120 and a storage unit coupled to vertical transistor 120. In some implementations, as shown in FIG. 1, the memory cell array is a DRAM cell array, and the storage unit is a capacitor 130 for storing charge as the binary information stored by the respective DRAM cell. In some other implementations not shown in the figures, the memory cell array is a phase-change material (PCM) cell array, and the storage unit can be a PCM element (e.g., including chalcogenide alloys) for storing binary information of the respective PCM cell based on the different resistivities of the PCM element in the amorphous phase and the crystalline phase.

As shown in FIG. 1, memory cells 110 may be arranged in a two-dimensional (2D) array having rows and columns. Memory device 100 may include word lines 150 coupling the memory cell array to peripheral circuits for controlling the switch of vertical transistors 120 in memory cells 110 located in a row, as well as bit lines 160 coupling the memory cell array to peripheral circuits for sending data to and/or receiving data from memory cells 110 located in a column. That is, each word line 150 is coupled to a respective row of memory cells 110, and each bit line 160 is coupled to one or more respective logic columns of memory cells 110. In some implementations, the gate of vertical transistor 120 is coupled to word line 150, one of the source, and the drain of vertical transistor 120 is coupled to bit line 160, the other one of the source, and the drain of vertical transistor 120 is coupled to one electrode of capacitor 130, and the other electrode of capacitor 130 is coupled to the ground.

Consistent with the scope of the present disclosure, vertical transistors 120, such as vertical metal-oxide-semiconductor field-effect transistors (MOSFETs), can replace the conventional planar transistors as the pass transistors of memory cells 110 to reduce the area occupied by the pass transistors, the coupling capacitance, as well as the interconnect routing complexity, as described below in detail.

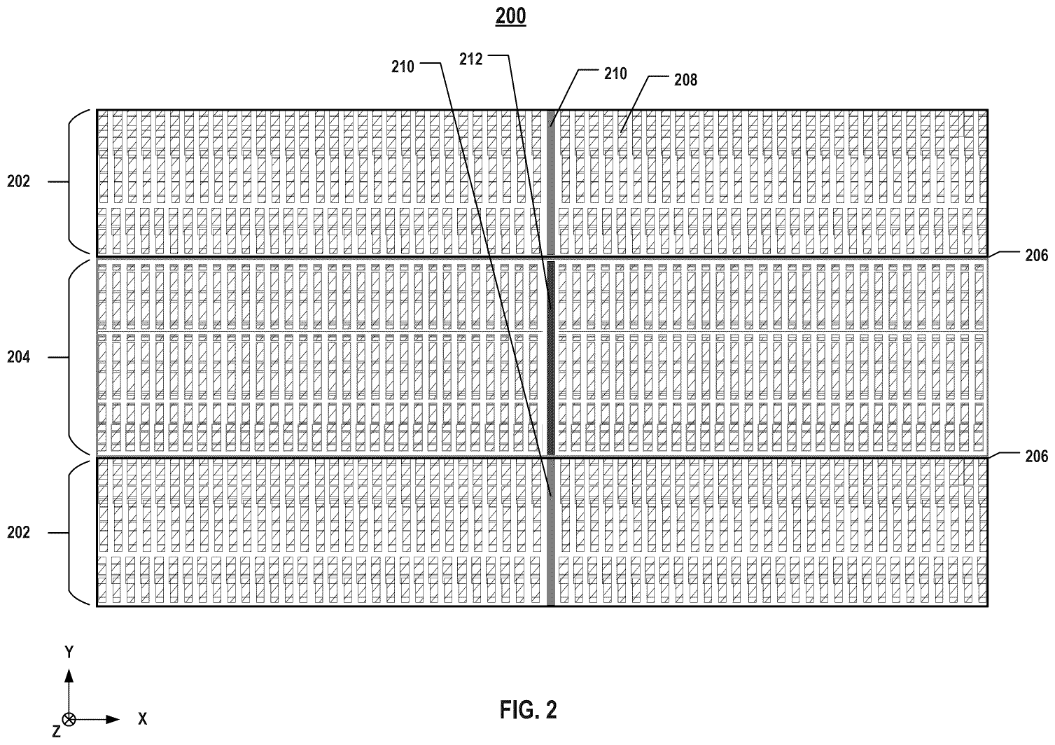

FIG. 2 illustrates a schematic plan view of a portion of an exemplary peripheral circuit 200, according to some implementations of the present disclosure. As shown in FIG. 2, the peripheral circuit 200 includes multiple doping regions, e.g., multiple p-well regions 202 and multiple n-well regions 204. In some implementations, the p-well regions 202 and the n-well regions 204 extend along the same direction in a plan view of peripheral circuit 200, e.g., the X-direction in FIG. 2. In some implementations, the p-well region 202 includes a p-doped semiconductor region, and the n-well region 204 includes an n-doped semiconductor region.

In some implementations, each p-well region 202 and/or n-well region 204 includes multiple transistor devices 208. In some implementations, the arrangement of the electrodes in each transistor device 208 may be along the Y-direction, and the arrangement of the electrodes in each transistor device 208 will be discussed later.

In some implementations, the p-well region 202 and the n-well region 204 are separated by a well boundary. In some implementations, the p-well region 202 and the n-well region 204 are separated by an isolation structure 206. In some implementations, the isolation structure 206 extends along the X-direction between the p-well region 202 and the n-well region 204. In some implementations, the isolation structure 206 is formed by a dielectric structure, i.e., a shallow trench isolation structure. In some implementations, the isolation structure 206 further extends along the Z-direction perpendicular to the X-direction and the Y-direction to separate the p-well region 202 and the n-well region 204.

As shown in FIG. 2, a p tap structure 210 is formed in the p-well region 202, and an n tap structure 212 is formed in the n-well region 204. In some implementations, the p tap structure 210 and the n tap structure 212 extend along the Y-direction in the plan view of peripheral circuit 200. In some implementations, the arrangement direction of the electrodes in each transistor device 208 and the extension direction of the p tap structure 210 and the n tap structure 212 are in the same direction, e.g., the Y-direction in FIG. 2.

It is understood that, only one p tap structure 210 is shown in each p-well region 202 and only one n tap structure 212 is shown in each n-well region 204 in FIG. 2, but the amount of the p tap structure 210 and/or the n tap structure 212 in each p-well region 202 and/or n-well region 204 may be changed or increased based on different design requirements. In some implementations, in each p-well region 202, multiple transistor devices 208 may be arranged between two p tap structures 210. In some implementations, in each n-well region 204, multiple transistor devices 208 may be arranged between two n tap structures 212.

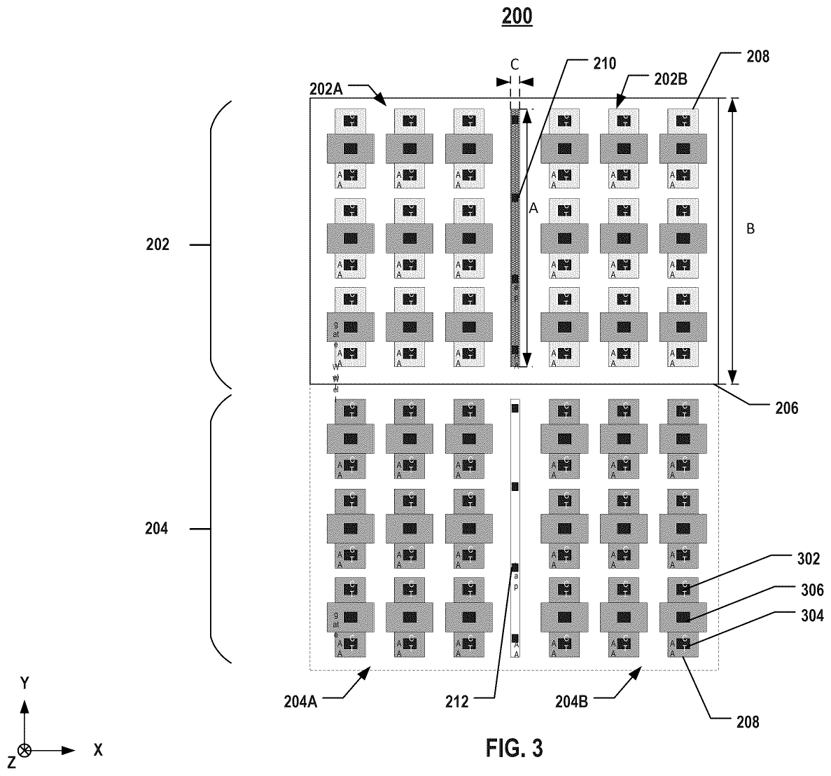

FIG. 3 illustrates a schematic plan view of a portion of the peripheral circuit 200, according to some implementations of the present disclosure. As shown in FIG. 3, each p-well region 202 and/or n-well region 204 includes multiple transistor devices 208. In some implementations, peripheral circuit 200 includes a first doping region, e.g., the p-well region 202, a first array of transistor structures 202A, a second array of transistor structures 202B, and a first tap structure, e.g., the p tap structure 210. The first array of transistor structures 202A and the second array of transistor structures 202B are arranged in the p-well region 202 configured in a first direction, e.g., the Y-direction, and a second direction perpendicular to the first direction, e.g., the X-direction.

Each transistor device 208 of the first array of transistor structures 202A and the second array of transistor structures 202B includes a source structure 302, a gate structure 306, and a drain structure 304 arranged along the Y-direction in a plan view of the semiconductor device. The first tap structure, e.g., the p tap structure 210, is arranged between the first array of transistor structures 202A and the second array of transistor structures 202B extending in the Y-direction. In other words, the arrangement direction of the electrodes in each transistor device 208 and the extension direction of the p tap structure 210 and the n tap structure 212 are in the same direction, e.g., the Y-direction.

As shown in FIG. 3, the p tap structure 210 has a length A and a width C in the plan view of the peripheral circuit 200. In some implementations, the width C of the p tap structure 210 in the plan view of the peripheral circuit 200 in the X-direction is between 80 nm and 120 nm. In some implementations, the width C of the p tap structure 210 in the plan view of the peripheral circuit 200 in the X-direction is between 90 nm and 110 nm. In some implementations, the width C of the p tap structure 210 in the plan view of the peripheral circuit 200 in the X-direction is about 100 nm. In some implementations, the p-well region 202 has a length B in the plan view of the peripheral circuit 200 in the Y-direction, and the p tap structure 210 has a length A in the plan view of the peripheral circuit 200 in the Y-direction. In some implementations, the length B is greater than the length A in the Y-direction.

The peripheral circuit 200 further includes a second doping region, e.g., the n-well region 204, adjacent to the first doping region along the Y-direction. A third array of transistor structures 204A, a fourth array of transistor structures 204B, and a second tap structure, e.g., the n tap structure 212, are arranged in the second doping region. In some implementations, the third array of transistor structures 204A and the fourth array of transistor structures 204B are arranged in the second doping region configured in the X-direction and the Y-direction perpendicular to the X-direction. The n tap structure 212 is arranged between the third array of transistor structures 204A and the fourth array of transistor structures 204B extending in the Y-direction.

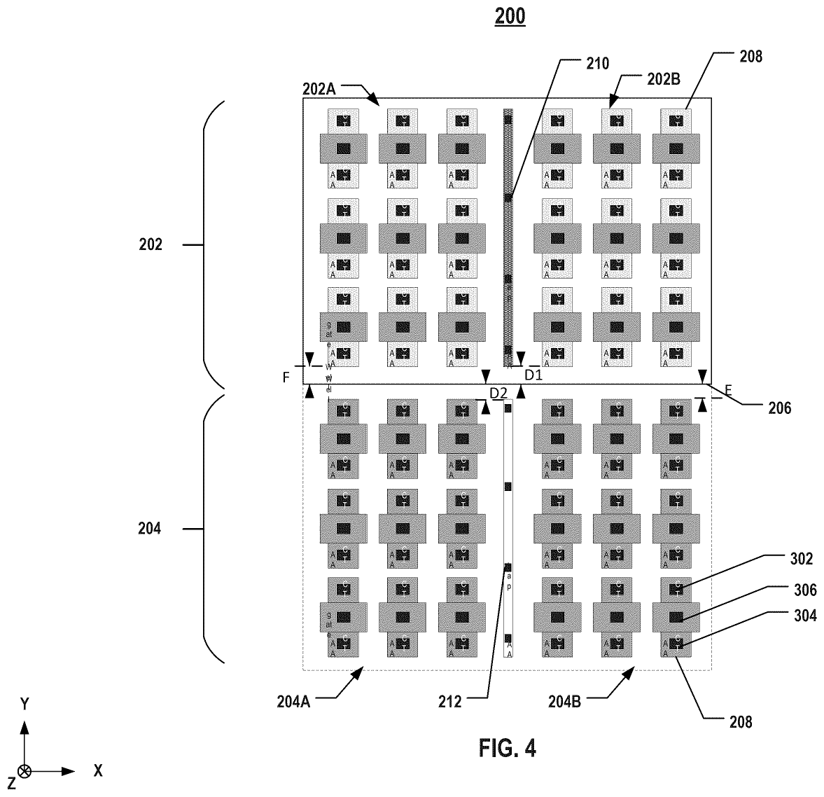

FIG. 4 illustrates a schematic plan view of a portion of the peripheral circuit 200, according to some implementations of the present disclosure. As shown in FIG. 4, the p-well region 202 and the n-well region 204 are separated by the isolation structure 206. The isolation structure 206 is located at the boundary of the p-well region 202 and the n-well region 204. In some implementations, the isolation structure 206 extends along the X-direction between the p-well region 202 and the n-well region 204. In some implementations, the isolation structure 206 is formed by a dielectric structure, i.e., a shallow trench isolation structure. In some implementations, the isolation structure 206 further extends along the Z-direction perpendicular to the X-direction and the Y-direction to separate the p-well region 202 and the n-well region 204.

The isolation structure 206, which is located at the boundary of the p-well region 202 and the n-well region 204, and the first array of transistor structures 202A and/or the second array of transistor structures 202B has a distance F in the Y-direction in the plan view of the peripheral circuit 200, as shown in FIG. 4. The isolation structure 206, which is located at the boundary of the p-well region 202 and the n-well region 204, and the third array of transistor structures 204A and/or the fourth array of transistor structures 204B has a distance E in the Y-direction in the plan view of the peripheral circuit 200, as shown in FIG. 4. In some implementations, the distance E is equal to the distance F.

In some implementations, the p tap structure 210 and the isolation structure 206, which is located at the boundary of the p-well region 202 and the n-well region 204, have a distance D1 in the Y-direction in the plan view of the peripheral circuit 200, as shown in FIG. 4. In some implementations, the distance D1 is between 10 nm and 500 nm. In some implementations, the distance D1 is between 50 nm and 300 nm. In some implementations, the distance D1 is between 80 nm and 200 nm.

In some implementations, the n tap structure 212 and the isolation structure 206, which is located at the boundary of the p-well region 202 and the n-well region 204, have a distance D2 in the Y-direction in the plan view of the peripheral circuit 200, as shown in FIG. 4. In some implementations, the distance D1 is equal to the distance D2.

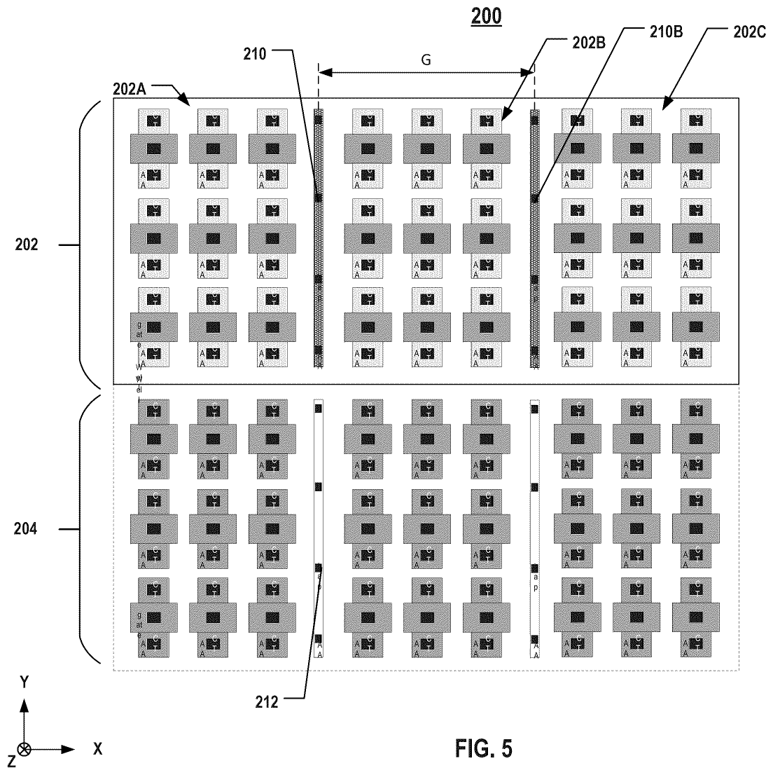

FIG. 5 illustrates a schematic plan view of a portion of the peripheral circuit 200, according to some implementations of the present disclosure. As shown in FIG. 5, the p-well region 202 may include the p tap structure 210 and a p tap structure 210B. In some implementations, the p tap structure 210 is located between the first array of transistor structures 202A and the second array of transistor structures 202B. In some implementations, the p tap structure 210B is located between the second array of transistor structures 202B and a fifth array of transistor structures 202C. It is understood that each of the first array of transistor structures 202A, the second array of transistor structures 202B, and/or the fifth array of transistor structures 202C may include multiple transistor devices arranged in multiple rows and/or multiple columns. The amount of transistor devices shown in the figures is for illustration purposes only, not for showing the actual amount of transistor devices.

The p tap structure 210 and the p tap structure 210B are separated by a distance G in the X-direction in the plane view of the peripheral circuit 200. In some implementations, the distance G is between 0 and 200 μm. In some implementations, the distance G is between 0 and 150 μm. In some implementations, the distance G is between 0 and 100 μm.

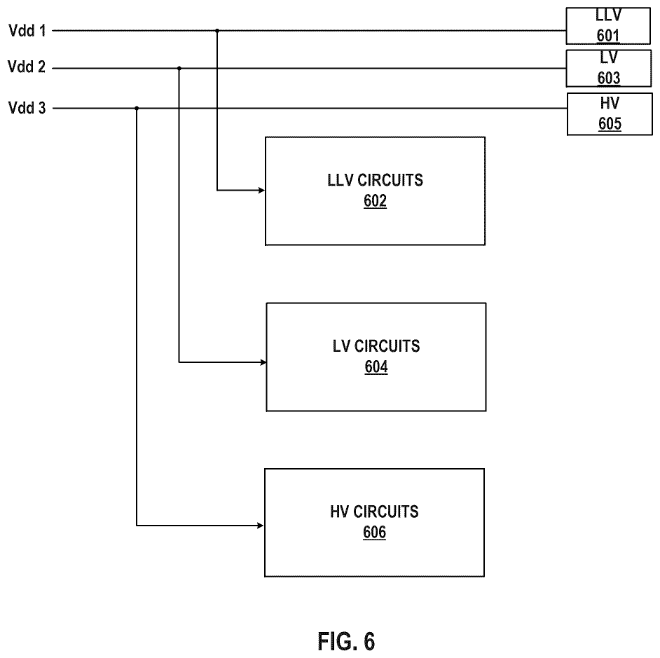

Different from logic devices (e.g., microprocessors), memory devices, such as 3D NAND Flash memory, require a wide range of voltages to be supplied to different memory peripheral circuits. For example, FIG. 6 illustrates a block diagram of peripheral circuits provided with various voltages, according to some aspects of the present disclosure. In some implementations, a memory device (e.g., memory device 100) includes a low low voltage (LLV) source 601, a low voltage (LV) source 603, and a high voltage (HV) source 605, each of which is configured to provide a voltage at a respective level (Vdd1, Vdd2, or Vdd3). For example, Vdd3>Vdd2>Vdd1. Each voltage source 601, 603, or 605 can receive a voltage input at a suitable level from an external power source (e.g., a battery). Each voltage source 601, 603, or 605 can also include voltage converters and/or voltage regulators to convert the external voltage input to the respective level (Vdd1, Vdd2, or Vdd3) and maintain and output the voltage at the respective level (Vdd1, Vdd2, or Vdd3) through a corresponding power rail.

In some implementations, LLV source 601 is configured to provide a voltage below 1.3 V, such as between 0.9 V and 1.2 V (e.g., 0.9 V, 0. 95 V, 1 V, 1.05 V, 1.1 V, 1.15 V, 1.2 V, any range bounded by the lower end by any of these values, or in any range defined by any two of these values). In one example, the voltage is 1.2 V. In some implementations, LV source 603 is configured to provide a voltage between 1.3 V and 3.3 V (e.g., 1.3 V, 0. 1.4 V, 1.5 V, 1.6 V, 1.7 V, 1.8 V, 1.9 V, 2 V, 2.1 V, 2.2 V, 2.3 V, 2.4 V, 2.5 V, 2.6 V, 2.7 V, 2.8 V, 2.9 V, 3V, 3.1V, 3.2 V, 3.3 V, any range bounded by the lower end by any of these values, or in any range defined by any two of these values). In one example, the voltage is 3.3 V. In some implementations, HV source 605 is configured to provide a voltage greater than 3.3 V, such as between 5 V and 30 V (e.g., 5 V, 6 V, 7 V, 8 V, 9 V, 10 V, 11 V, 12 V, 13 V, 14 V, 15 V, 16 V, 17 V, 18 V, 19 V, 20 V, 21 V, 22 V, 23 V, 24 V, 25 V, 26 V, 27 V, 28 V, 29 V, 30 V, any range bounded by the lower end by any of these values, or in any range defined by any two of these values). It is understood that the voltage ranges described above with respect to HV source 605, LV source 603, and LLV source 601 are for illustrative purposes and non-limiting, and any other suitable voltage ranges may be provided by HV source 605, LV source 603, and LLV source 601.

Based on their suitable voltage levels (Vdd1, Vdd 2, or Vdd3), the memory peripheral circuits (e.g., peripheral circuit 200) can be categorized into LLV circuits 602, LV circuits 604, and HV circuits 606, which can be coupled to LLV source 601, LV source 603, and HV source 605, respectively. The arrangement of the well taps, e.g., the p tap structure 210 and/or the n tap structure 212, extending in the Y-direction between the array of transistor structures could effectively reduce the whole planar areas of the peripheral circuit 200.

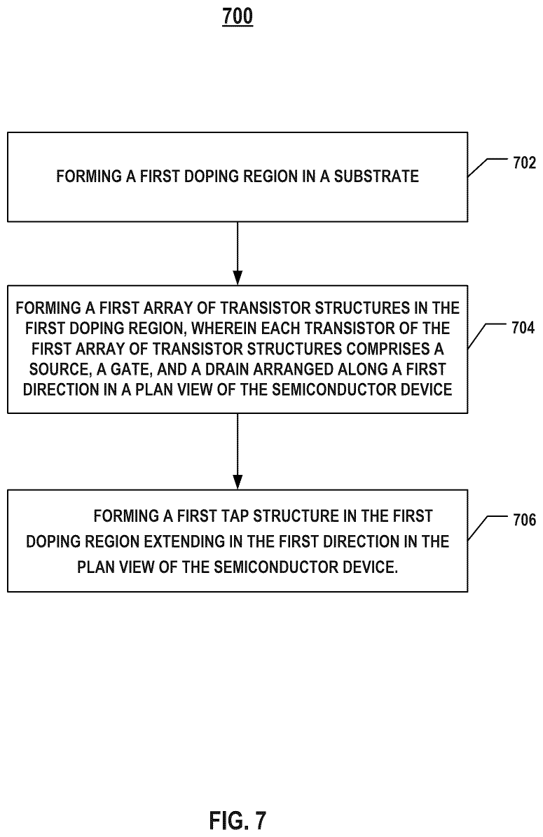

FIG. 7 illustrates a flowchart of a method 700 for forming a semiconductor device, according to some aspects of the present disclosure. As shown in FIG. 7, in operation 702, a first doping region is formed in a substrate. In some implementations, the first doping region may be a n-doped well region or a p-doped well region. In some implementations, the first doping region may be the p-well region 202, as shown in FIGS. 2-5.

In operation 704, a first array of transistor structures is formed in the first doping region. In some implementations, the first array of transistor structures may be the first array of transistor structures 202A, and/or the second array of transistor structures 202B, as shown in FIGS. 2-5. In some implementations, each transistor of the first array of transistor structures includes a source structure 302, a gate structure 306, and a drain structure 304 arranged along the Y-direction in a plan view of the semiconductor device.

In operation 706, a first tap structure, e.g., the p tap structure 210, is formed in the first doping region extending in the Y-direction in the plan view of the semiconductor device.

In some implementations, a second doping region, e.g., the n-well region 204, is formed adjacent to the first doping region along the Y-direction in the substrate. The first doping region and the second doping region are separated by the isolation structure 206. In some implementations, a second array of transistor structures, e.g., the third array of transistor structures 204A, and/or the fourth array of transistor structures 204B, is formed in the second doping region. In some implementations, a second tap structure, e.g., the n tap structure 212, is formed in the second doping region extending in the Y-direction in the plan view of the semiconductor device.

The isolation structure 206, which is located at the boundary of the p-well region 202 and the n-well region 204, and the first array of transistor structures 202A and/or the second array of transistor structures 202B has a distance F in the Y-direction in the plan view of the peripheral circuit 200, as shown in FIG. 4. The isolation structure 206, which is located at the boundary of the p-well region 202 and the n-well region 204, and the third array of transistor structures 204A and/or the fourth array of transistor structures 204B has a distance E in the Y-direction in the plan view of the peripheral circuit 200, as shown in FIG. 4. In some implementations, the distance E is equal to the distance F.

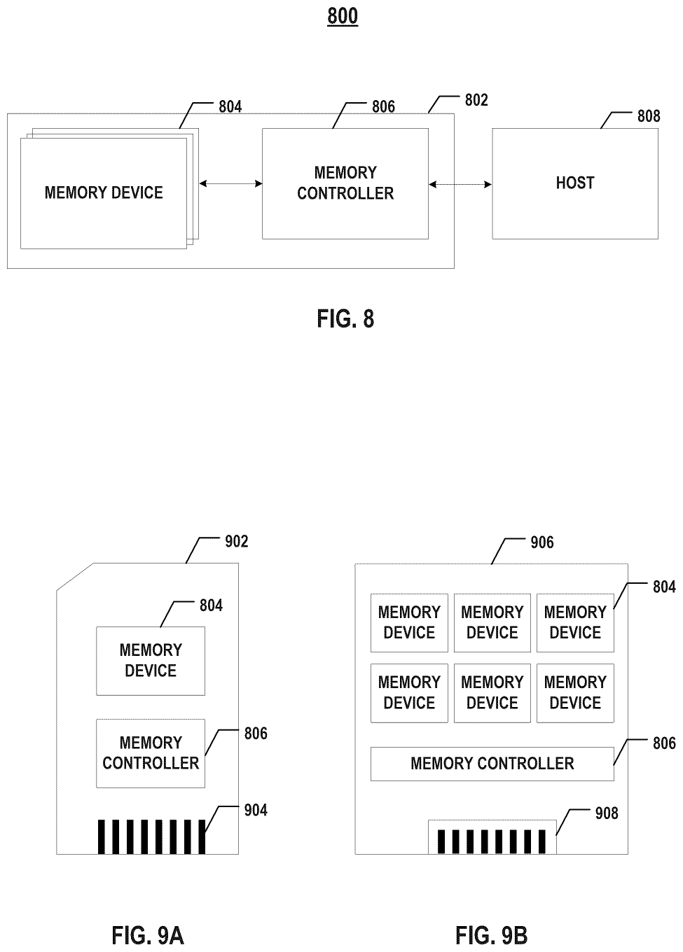

FIG. 8 illustrates a block diagram of a system 800 having a memory device, according to some aspects of the present disclosure. System 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, system 800 can include a host 808 and a memory system 802 having one or more memory devices 804 and a memory controller 806. Host 808 can be a processor of an electronic device, such as a central processing unit (CPU), or a system-on-chip (SoC), such as an application processor (AP). Host 808 can be configured to send or receive the data to or from memory devices 804.

Memory device 804 can be any memory devices disclosed herein, such as memory device 100 shown in FIGS. 2-5. In some implementations, each memory device 804 includes an array of memory cells, a first peripheral circuit of the array of memory cells, and a second peripheral circuit of the array of memory cells, which are stacked over one another in different planes, as described above in detail. The first peripheral circuit and the second peripheral circuit can be any peripheral circuit disclosed herein, such as peripheral circuit 200 shown in FIGS. 2-5.

Memory controller 806 is coupled to memory device 804 and host 808 and is configured to control memory device 804, according to some implementations. Memory controller 806 can manage the data stored in memory device 804 and communicate with host 808. In some implementations, memory controller 806 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed for operating in a high duty-cycle environment SSDs or embedded multi-media-cards (eMMCs) used as data storage for mobile devices, such as smartphones, tablets, laptop computers, etc., and enterprise storage arrays. Memory controller 806 can be configured to control operations of memory device 804, such as read, erase, and program operations. In some implementations, memory controller 806 is configured to control the array of memory cells through the first peripheral circuit and the second peripheral circuit. Memory controller 806 can also be configured to manage various functions with respect to the data stored or to be stored in memory device 804 including, but not limited to bad-block management, garbage collection, logical-to-physical address conversion, wear leveling, etc. In some implementations, memory controller 806 is further configured to process error correction codes (ECCs) with respect to the data read from or written to memory device 804. Any other suitable functions may be performed by memory controller 806 as well, for example, formatting memory device 804. Memory controller 806 can communicate with an external device (e.g., host 808) according to a particular communication protocol. For example, memory controller 806 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 806 and one or more memory devices 804 can be integrated into various types of storage devices, for example, be included in the same package, such as a universal Flash storage (UFS) package or an eMMC package. That is, memory system 802 can be implemented and packaged into different types of end electronic products. In one example as shown in FIG. 9A, memory controller 806 and a single memory device 804 may be integrated into a memory card 902. Memory card 902 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 902 can further include a memory card connector 904 coupling memory card 902 with a host (e.g., host 808 in FIG. 8). In another example as shown in FIG. 9B, memory controller 806 and multiple memory devices 804 may be integrated into an SSD 906. SSD 906 can further include an SSD connector 908 coupling SSD 906 with a host (e.g., host 808 in FIG. 8). In some implementations, the storage capacity and/or the operation speed of SSD 906 is greater than those of memory card 902.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A semiconductor device, comprising:
a memory structure; and
a peripheral structure coupled to the memory structure,
wherein the peripheral structure comprises a first doping region, a first array of transistor structures, a second array of transistor structures, and a first tap structure, wherein the first array of transistor structures and the second array of transistor structures are arranged in the first doping region configured in a first direction and a second direction perpendicular to the first direction;
each transistor of the first array of transistor structures and the second array of transistor structures comprises a source structure, a gate structure, and a drain structure arranged along the first direction in a plan view of the semiconductor device; and
the first tap structure is arranged between the first array of transistor structures and the second array of transistor structures extending in the first direction.

2. The semiconductor device of claim 1, wherein a width of the first tap structure in the plan view of the semiconductor device in the second direction is between 80 nm and 120 nm.

3. The semiconductor device of claim 1, wherein a first length of the first doping region in the plan view of the semiconductor device in the first direction is greater than a second length of the first tap structure in the plan view of the semiconductor device in the first direction.

4. The semiconductor device of claim 1, wherein
the peripheral structure further comprises a second doping region adjacent to the first doping region along the first direction, a third array of transistor structures, a fourth array of transistor structures, and a second tap structure;
the third array of transistor structures and the fourth array of transistor structures are arranged in the second doping region configured in the first direction and the second direction perpendicular to the first direction;
the second tap structure is arranged between the third array of transistor structures and the fourth array of transistor structures extending in the first direction; and
a first distance between a boundary of the first doping region and the second doping region and the first array of transistor structures is equal to a second distance between the boundary and the third array of transistor structures.

5. The semiconductor device of claim 4, wherein a third distance between the boundary and the first tap structure is between 10 nm and 500 nm.

6. The semiconductor device of claim 5, wherein a fourth distance between the boundary and the second tap structure is equal to the third distance.

7. The semiconductor device of claim 4, wherein the first doping region is a p-well region, the second doping region is an n-well region, and the first doping region and the second doping region are separated by an isolation structure.

8. The semiconductor device of claim 7, wherein the first tap structure is a p-well tap structure and the second tap structure is an n-well tap structure.

9. The semiconductor device of claim 1, wherein
the peripheral structure further comprises a third tap structure arranged in the first doping region; and
the second array of transistor structures is between the first tap structure and the third tap structure in the second direction in the plan view of the semiconductor device.

10. The semiconductor device of claim 9, wherein a fifth distance between the first tap structure and the third tap structure in the second direction is between 0 and 200 μm.

11. A semiconductor device, comprising:
a memory structure; and
a peripheral structure coupled to the memory structure, comprising:
a first doping region;
a first array of transistor structures arranged in the first doping region; and
a first tap structure arranged in the first doping region,
wherein each transistor of the first array of transistor structures comprises a source structure, a gate structure, and a drain structure arranged along a first direction in a plan view of the semiconductor device, and the first tap structure extends in the first direction.

12. The semiconductor device of claim 11, wherein the peripheral structure further comprises:
a second doping region adjacent to the first doping region along the first direction, and the first doping region and the second doping region are separated by an isolation structure;
a second array of transistor structures arranged in the second doping region; and
a second tap structure arranged in the second doping region extending in the first direction.

13. The semiconductor device of claim 12, wherein a first distance between a boundary of the first doping region and the second doping region and the first array of transistor structures is equal to a second distance between the boundary and the second array of transistor structures.

14. The semiconductor device of claim 12, wherein a third distance between a boundary of the first doping region and the second doping region and the first tap structure is equal to a fourth distance between the boundary and the second tap structure.

15. The semiconductor device of claim 11, wherein a width of the first tap structure in the plan view of the semiconductor device in a second direction perpendicular to the first direction is between 80 nm and 120 nm.

16. The semiconductor device of claim 11, wherein a first length of the first doping region in the plan view of the semiconductor device in the first direction is greater than a second length of the first tap structure in the plan view of the semiconductor device in the first direction.

17. A method of forming a semiconductor device, comprising:
forming a first doping region in a substrate;
forming a first array of transistor structures in the first doping region, wherein each transistor of the first array of transistor structures comprises a source, a gate, and a drain arranged along a first direction in a plan view of the semiconductor device; and
forming a first tap structure in the first doping region extending in the first direction in the plan view of the semiconductor device.

18. The method of claim 17, further comprising:
forming a second doping region adjacent to the first doping region along the first direction in the substrate, wherein the first doping region and the second doping region are separated by an isolation structure;
forming a second array of transistor structures in the second doping region; and
forming a second tap structure in the second doping region extending in the first direction in the plan view of the semiconductor device.

19. The method of claim 18, wherein a first distance between a boundary of the first doping region and the second doping region and the first array of transistor structures is equal to a second distance between the boundary and the second array of transistor structures.

20. The method of claim 18, wherein a third distance between a boundary of the first doping region and the second doping region and the first tap structure is equal to a fourth distance between the boundary and the second tap structure.
